(19) United States
(12) Patent Application Publication
(10) Pub. No.: US 2026/0076198 A1
(43) Pub. Date: Mar. 12, 2026

(54) MULTI-CHIPLETS PACKAGING FOR JET-COOLED, DIAMOND-SUBSTRATED CHIPS

(71) Applicant: Diamond Foundry Inc., South San Francisco, CA (US)

(72) Inventors: Jeroen Van Duren, Fremont, CA (US); Martin Roscheisen, San Francisco, CA (US)

(21) Appl. No.: 19/297,112

(22) Filed: Aug. 12, 2025

Related U.S. Application Data
(60) Provisional application No. 63/691,630, filed on Sep. 6, 2024.
(60) Provisional application No. 63/703,607, filed on Oct. 4, 2024.
(60) Provisional application No. 63/715,488, filed on Nov. 1, 2024.
(60) Provisional application No. 63/763,416, filed on Feb. 26, 2025.
(60) Provisional application No. 63/777,001, filed on Mar. 25, 2025.

(51) Int. Cl. H01L 23/473; H01L 23/373; H01L 25/18; H10B 80/00; H10D 80/30

(52) U.S. Cl. CPC H10W 40/475; H10B 80/00; H10D 80/30; H10W 40/254; H10W 90/00

(57) ABSTRACT

A device package and heatsink assembly includes a device package containing one or more logic elements and one or more other integrated circuit devices mounted to a package substrate and one or more heatsinks. The other integrated circuit devices are higher above the package substrate's surface than the logic elements. Each heatsink contains chambers for a fluid heat transfer medium. A surface of the logic elements is thermally coupled to the fluid. A semiconductor chip package fabrication method includes bonding a diamond-containing dielet to a semiconductor logic die to form a logic die structure; mounting the logic die structure to a package substrate with the logic die sandwiched between the dielet and the substrate, exposing a surface of the dielet; and mounting one or more other integrated circuit devices to the package substrate. The other integrated circuit devices are higher above the package substrate's surface than the logic die structure.

### CLAIM OF PRIORITY

This application claims the priority benefit of U.S. Provisional Application Number 63/777,001 to Martin Roscheisen et al. filed Mar. 25, 2025, the entire contents of which are incorporated herein by reference. This application claims the priority benefit of U.S. Provisional Application Number 63/763,416 to Martin Roscheisen et al. filed Feb. 26, 2025, the entire contents of which are incorporated herein by reference and included herein as Appendix A. This application claims the priority benefit of U.S. Provisional Application Number 63/715,488 to Martin Roscheisen et al. filed Nov. 1, 2024, the entire contents of which are incorporated herein by reference. This application claims the priority benefit of U.S. Provisional Application Number 63/703,607 to Jeroen K. J. Van Duren et al. filed Oct. 4, 2024, the entire contents of which are incorporated herein by reference. This application claims the priority benefit of U.S. Provisional Patent Application number 63/691,630 to Jeroen K. J. Van Duren and Martin R. Roscheisen, filed Sep. 6, 2024, the entire contents of which are incorporated herein by reference.

### CROSS REFERENCE TO RELATED APPLICATIONS

This application is related to U.S. Provisional Patent Application number 63/539,983 to Jeroen K. J. Van Duren and Martin R. Roscheisen, filed Sep. 22, 2023, the entire contents of which are incorporated herein by reference. This application is also related to International Patent Application Number PCT/US23/86169 filed Dec. 28, 2023, the entire contents of which are incorporated herein by reference. This application is also related to International Patent Application Number PCT/US24/30242, filed May 20, 2024, the entire contents of which are incorporated herein by reference. This application is also related to U.S. patent application Ser. No. 18/761,091, filed Jul. 1, 2024, the entire contents of which are incorporated herein by reference.

### BACKGROUND

It is well known that diamond conducts heat very well and can serve as a heat spreader in electronics devices. This holds for both single crystal and polycrystalline diamond. It is advantageous to integrate a diamond layer between an integrated circuit device and a heat sink in a die stack. The advantage of integrating a layer of diamond, e.g., single crystal diamond (SCD), into a stack with an integrated circuit (IC) semiconductor die is that the diamond layer efficiently spreads the heat generated by the IC die during operation. Such heat spreading reduces the formation of localized “hot spots” that can negatively impact device performance, power consumption, and reliability.

Previous patent applications, such as U.S. patent application Ser. No. 19/044,723, have focused on (1) integrating polished SCD dies into the final customer chip package, (2) “height matching” SCD-based dies with high-bandwidth memory (HBM) in an advanced package by use of a filler material instead of just thick SCD, since thick SCD is costly, (3) introducing a “smoothening material” or “compliant bond material” to allow for less SCD polishing, since polishing SCD is difficult, and (4) integrating diamond-based materials as part of a reconstituted wafer to facilitate integration into a wafer-based process flow as commonly applied in semiconductor foundries. The benefit of SCD heat spreading can be further improved by tackling thermal resistance not just on a chip level or package level, but also on a system level.

It is within this context that aspects of the present disclosure arise.

### BRIEF DESCRIPTION OF THE DRAWINGS

FIG. 1 is a side view schematic diagram illustrating a chip package in which a diamond dielet is direct bonded to a thinned semiconductor logic die with jet impingement direct cooling through an exposed surface of the diamond-containing die according to certain aspects of the present disclosure.

FIG. 2 is a sequence of side view cross-sectional schematic diagrams illustrating a conventional chip-on-wafer-on-substrate (CoWoS) packaging process.

FIG. 3 is a sequence of side view cross-sectional schematic diagrams illustrating an implementation of a chip-on-wafer-on-substrate (CoWoS) packaging process according to aspects of the present disclosure.

FIG. 4 is a sequence of side view cross-sectional schematic diagrams illustrating an implementation of an alternative chip-on-wafer-on-substrate (CoWoS) packaging process according to aspects of the present disclosure.

FIG. 5 is a sequence of side view cross-sectional schematic diagrams illustrating an implementation of yet another alternative chip-on-wafer-on-substrate (CoWoS) packaging process according to aspects of the present disclosure.

FIGS. 6A through 6C are side view cross-section schematic diagrams illustrating different implementations of a die package with jet cooling according to certain aspects of the present disclosure.

FIG. 6D is a side-view cross-section schematic diagram illustrating an implementation of a die package with jet cooling and immersion cooling according to certain aspects of the present disclosure.

FIG. 7A through FIG. 7D are three-dimensional diagrams illustrating a device package and heatsink assembly having a jet cooler that may be used in conjunction with a chip package according to aspects of the present disclosure.

FIG. 8 is a three-dimensional schematic diagram illustrating a side of a chip package showing a possible configuration of high-bandwidth-memory (HBM) stacks and logic dies.

### DETAILED DESCRIPTION

### Introduction

Thermal issues have recently become high priority since it limits the performance, reliability and energy efficiency of high-power advanced chip packages, e.g., AI chips. These thermal issues can be reduced by reducing chip, package, and system level thermal resistance. Minimizing hot spots by improved heat spreading combined with more aggressive cooling reduces overall thermal issues. Diamond-based materials improve heat spreading extraordinarily and when combined with jet impingement cooling directly onto the diamond-based surface provides an extraordinary leap forward in thermal management. Integrating diamond, e.g., single crystal diamond (SCD) into the fabrication of advanced high-power multi-chiplets packages faces challenges based on the diamond typically being thinner than the original semiconductor material in device chips. This causes issues with standard chip-on-wafer-on-substrate (CoWoS) chip packaging processing requiring a level surface for subsequent processing. Furthermore diamond, being a very hard material, also causes issues in standard CoWoS processing flow, particularly during the planarization.

It is often prohibitively expensive or impractical to fabricate an SCD wafer or a polycrystalline diamond (PCD) wafer of certain standard semiconductor wafer diameters, such as 300 mm or 450 mm, with semiconductor surface specifications. Previous applications, such as U.S. Provisional patent applications numbers 63/691,630, 63/703,607, 63/715,488 and 63/763,416, have described production of reconstituted wafers having an array of diamond (e.g. SCD or PCD) dies or diamond die stacks that can be shipped to a semiconductor device fabrication plant (sometimes called a “fab” or “foundry”) in a configuration that is compatible with semiconductor processing done by the plant. The same holds for shipping to Outsourced Assembly and Test (OSAT) facilities. As used herein, a “reconstituted wafer” refers to a wafer where multiple diamond (e.g. SCD or PCD) dies are placed on a temporary or permanent carrier wafer. However, there are a number of technical challenges to configuring and fabricating such a reconstituted wafer.

One challenge of diamond die fabrication is to make the diamond die surface smooth enough for bonding and to make the diamond die thickness tolerance tight enough for bonding. In some implementations a smoothening layer or compliant layer may be used between the diamond die and the layers above and/or below it to ensure the desired smoothness and/or thickness tolerance.

Another challenge is that the surface of the diamond die or smoothening material may be incompatible with typical semiconductor fabrication processes. To address such challenges, in some implementations a wafer, e.g., a silicon wafer, may be bonded to the logic-facing surface of the diamond dies or die stacks and thinned, e.g., to <100 [symbol] m or <10 [symbol] m. The resulting stack may be easily bonded to a semiconductor wafer on which logic elements are formed. Making the wafer that is bonded to the diamond very thin adds little thermal resistance to the overall diamond die stack.

Yet another challenge is that the diamond dies or die stacks are typically placed on an underlying wafer (sometimes called a carrier wafer) with gaps between adjacent dies. Such gaps may present challenges during subsequent processing steps. For example, the gaps may lead to structural support issues, e.g., if the diamond dies or die stacks are covered by a layer of material that is thinner than the width of the gaps, or if the diamond dies or die stacks are placed on a wafer that is significantly thinner than the width of the gaps. Furthermore, the gaps may present problems of edge rounding during subsequent surface finishing steps, e.g. during chemical mechanical polishing (CMP). Additionally, the gaps may trap contaminants that are hard to remove. To address such challenges, the gaps may be filled with appropriate gap-filling materials. Examples of this are described in U.S. Provisional Patent Application number 63/763,416, which is incorporated herein by reference.

Thermal resistance on a chip level can be reduced to a large extent by thinning the semiconductor wafer, e.g., by removing the silicon underneath the IC, e.g., by grinding. However, the mechanical integrity of the thinned IC dies needs to be maintained, e.g., by bonding the dies to another stiff material. However, this stiff material cannot add thermal resistance and needs to have a similar coefficient of thermal expansion (CTE).

An additional challenge associated with integration of diamond and semiconductors is that many applications require a copper layer, e.g. a copper lid, between the diamond-containing die and a heat sink. Unfortunately, there is a mismatch in the coefficient of thermal expansion (CTE) of copper and that of diamond. The CTE mismatch can lead to warpage of a diamond-copper composite stack.

Some solutions to the aforementioned problems involve use of diamond sandwiched between thin semiconductor layers, e.g., silicon (Si), as described in U.S. Provisional Patent Application number 63/763,416. Unfortunately, solutions involving large-diameter, e.g., 300 mm reconstituted SCD wafers may result in a thermal stack that includes as many as 10 thin-film layers as well as a thermal resistor of 400 micrometers (μm) of silicon on top of diamond. Additional consumables cost may include two sacrificial silicon wafers. The silicon on top of chip die reduces efficiency of jet impingement cooling. Finally, and perhaps most importantly, there are unresolved issues regarding exposed metals at the rim of the reconstituted wafer, outgassing of filler materials, dicing, etc. for wafer processing because a frontend chip fab is a tightly controlled environment.

To address these issues, aspects of the present disclosure propose changing the CoWoS flow, or any similar advanced multi-chiplets packaging flow where two or more chips are horizontally interconnected, towards including a chiplet that is at least 100 μm lower in height than the other chiplets and either filling it in completely with overmold or encapsulation material and/or adding a filler material that is temporarily bonded to the lower-height chiplet and then planarizing all chiplets while bridging over such lower height chiplet in a way that does not touch the lower height chiplet so that subsequent processing including flip & bump attachment is enabled as usual in the CoWoS-L, other CoWoS variants, and other multi-chiplets packages—and then at the end substantially opening the area above the lower-height chiplet again (via ablation, area focused grinding, or de-bonding of the temporary filler material using techniques used with temporary carriers, etc.) to expose its top surface, where such lower height chiplet can be a SCD or polycrystalline diamond (PCD) or other high thermal conductivity materials or combo of materials bonded to a chip in a variety of ways including laser assisted bonding, transient liquid phase bonding (TLPB), sintering, plasma-assisted bonding (PAB), surface activated bonding (SAB), or atomic diffusion bonding (ADB); and where the resultant package is liquid cooled including spray cooled or jet impingement cooled. TLPB may be similar to solid-liquid interdiffusion (SLID), and transient liquid phase sintering (TLPS).

According to aspects of the present disclosure minimal adaptation of CoWoS(-L) is described to enable the integration of diamond-containing dielets and substrated high-power chips into existing volume chip packaging flows for an outcome that is thermally optimal: direct jet impingement cooled diamond-containing dielets bonded to thinned-silicon chips in a non-lidded package or a lidded package with the lid substantially open above the diamond-containing dielets to allow for jet impingement

The following figures contain schematics that are not to scale.

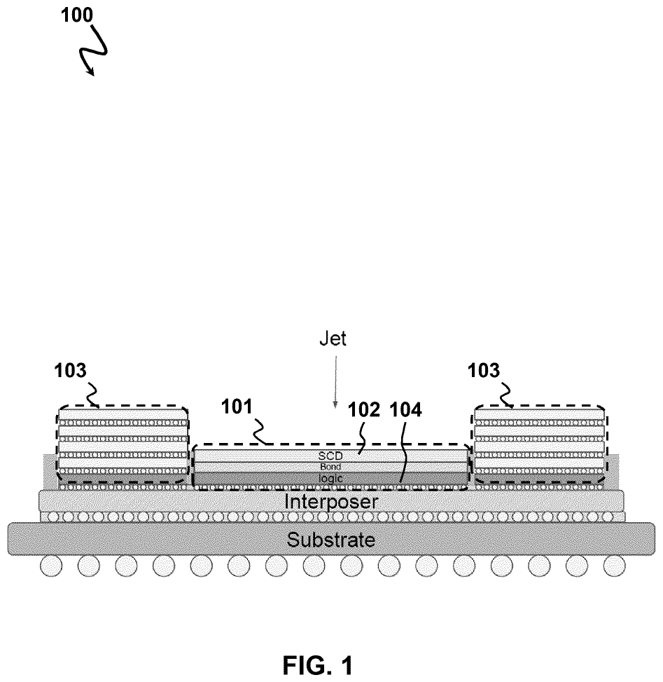

FIG. 1 depicts an example of a non-lidded semiconductor chip package 100 having a logic die structure 101 and one or more other taller integrated circuit devices 103, such as high-bandwidth memory (HBM) stacks. The logic die structure 101 includes a diamond-containing dielet 102 bonded to a logic die 104 made of a thinned semiconductor material, e.g., silicon, containing active transistors. The logic die 104 may be thinned to a few tens of microns thickness. The diamond-containing dielet 102 is exposed so that it may be directly liquid-cooled, e.g., with a jet impinging directly onto its exposed surface. The surface may be patterned to further enhance cooling. The liquid-cooled diamond-containing dielet 102 dissipates hotspots within the logic die 104 and efficiently removes heat. The exposed configuration avoids any CTE mismatch (warpage) with copper or aluminum in contact with a large area of the diamond-containing dielet, e.g. as a lid. This design may utilize a simple reliable cooling jet, e.g., only one single, fairly broad jet that is less prone to clogging. The cooling liquid may contain water. The cooling liquid may contain a dielectric fluid. The cooling fluid may contain a hydrocarbon or fluorochemical fluid.

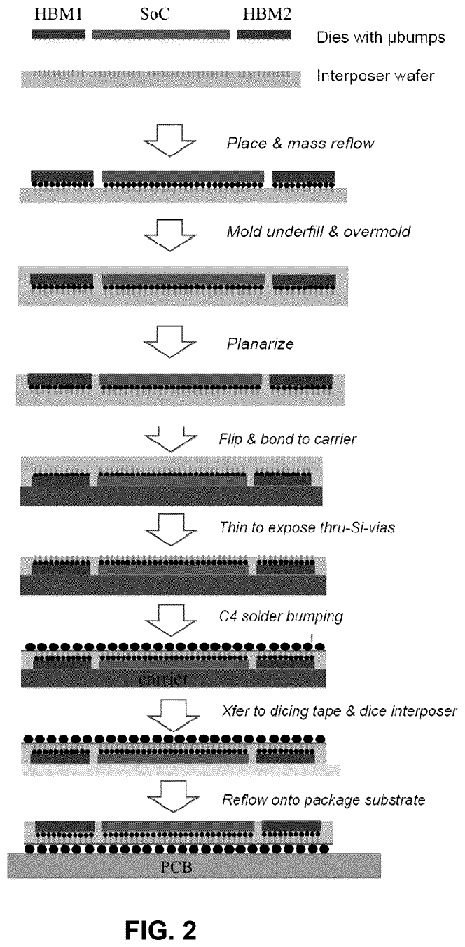

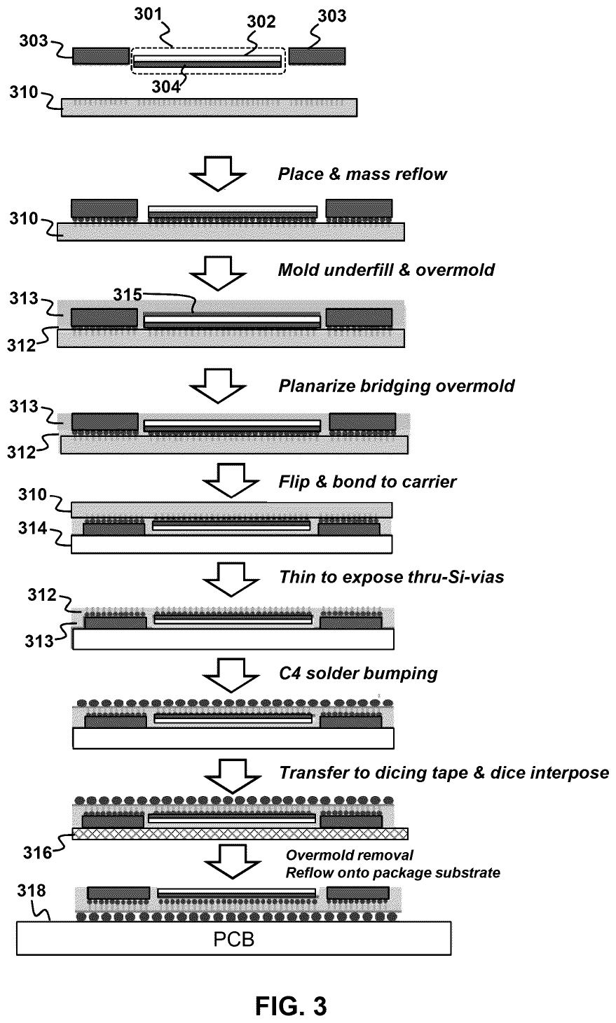

Aspects of the present disclosure include methods for fabricating a non-lidded chip package 100 of the type shown in FIG. 1. Existing process flows may be readily adapted due to the design of the above-described chip package. By way of example, and not by way of limitation, FIG. 2 and FIG. 3 illustrate an example of adapting a chip-on-wafer-on-substrate (CoWoS) process flow to enable integration of diamond-containing, e.g., single crystal diamond (SCD), substrates with high-power chips into existing volume chip packaging flows. This adaptation may apply generally to process flows where two or more chips are horizontally interconnected, e.g., by chip-on-interposer-on-substrate, or by embedded bridges. Chips may be horizontally interconnected by an interposer, an embedded silicon bridge, redistribution layers (RDL), or package substrates.

FIG. 2 illustrates a conventional CoWoS process flow. In the conventional process, logic and HBM dies with bumps, e.g. microbumps, are placed on an interposer wafer, or interposer substrate, e.g. an organic interposer. Here, the logic and HBM dies are of a similar height. The interposer wafer contains electrically conductive pathways, e.g., through-silicon vias (TSV), for subsequently connecting circuits in the logic and HBM dies to a package substrate, e.g. Ajinomoto Build-up Film (ABF) substrate. The interposer may be a wafer onto which multiple combinations of logic and HBM dies may be bonded and subsequently diced into separate die packages. The dies may be bonded to the interposer through a mass solder reflow process and then covered with a molding compound in underfill and overmold or encapsulation steps. After planarizing the molding compound, the resulting structure is flipped and bonded to the carrier wafer. The interposer is then thinned to expose its conductive pathways. Bumps, e.g. solder bumps, may be placed on the exposed conductive pathways and the interposer may be transferred to a dicing tape for dicing into separate die package sub-assemblies. Each sub-assembly may then be removed from the dicing tape, flipped again and bonded to a package substrate, e.g. ABF substrate.

According to aspects of the present disclosure a CoWoS process flow of the type depicted in FIG. 2 or other chip packaging process may be adapted at its overmold or encapsulation step to yield a packaged device having an open exposed diamond-containing dielet on the logic die while not affecting other CoWoS processes utilizing a planar backside. For example, FIG. 3 illustrates a possible implementation of a modified CoWoS process flow according to aspects of the present disclosure. Similar to the conventional process, logic die structures 301 and HBM dies 303 with bumps are placed on an interposer wafer 310. Here, the logic die structures 301 include a thinned semiconductor logic die 304 with a diamond-containing (e.g., SCD) dielet 302 bonded to it. The diamond-containing dielet may have a thermal conductivity higher than 2000 W/m-K. A main surface of a diamond-containing dielet 302 may have a crystal orientation of (100), (110), (111), or (113). Furthermore, unlike the conventional process, here the height of the logic die structures is less than that of the HBM dies 303. The lower height may avoid exposure of the diamond surface to the grinding wheel during the planarization. This grinding wheel is not designed to grind diamond-containing dielets 302, and may cause a severe increase in grinding wheel wear rate. The lower height may allow for reduced diamond-containing dielet thickness, thereby it may reduce diamond-containing dielet cost. The lower height may avoid the use of a gap filler to make up for the height with the HBM stack 303, where this gap filler needs to be of low thermal resistance. The gap filler adds thermal resistance; thereby it may reduce the efficacy of jet impingement cooling. The gap filler may add steps and cost. The gap filler may require copper or aluminum which may cause warpage due to a significant CTE mismatch with diamond-containing dielets.

The diamond-containing dielets 302 generally have the same shape and lateral dimensions (e.g., length and width) as the corresponding logic dies 304 to which they are bonded. There are a number of different ways to bond diamond-containing dies to the logic dies. For example, SCD, e.g. with an as-split surface finish, may be bonded using direct laser assisted bonding, e.g., laser melt bonding or laser compression bonding, which takes advantage of SCD's transparency by shining a laser through the SCD to partially melt a portion of the semiconductor material at the surface of the logic die 304. Alternatively, the diamond-containing die may be bonded to the logic die by sintering, e.g., with silver or copper, which is standard in power electronics. Furthermore, if lower temperature and/or lower force is desirable, transient liquid phase bonding (TLPB) may be used. Transient liquid phase bonding (TLPB), transient liquid phase sintering (TLPS), and solid-liquid interdiffusion (SLID) bonding may be performed by depositing thin precursor films onto the surfaces to be bonded, e.g. by sputtering or plating. Alternatively, the precursor materials may be introduced at the bondline as a coupon, or a sheet. In yet another implementation, the TLPB precursor materials may be introduced at the bondline as a paste. It should be understood that a combination of films, coupons, and paste may be used. TLPB uses a thin bond material of metal between the diamond-containing dielet and logic die. The metal may contain tin, indium or bismuth. The metal may contain copper, silver, or gold. The metal may contain two or more of these metals. TLPB may be performed by bonding at a temperature slightly above the melting temperature of the metal with the lowest melting point to form an alloy with a higher melting point. Laser-assisted bonding, sintering, and TLPB may be used with rough diamond-containing dielets. Ultra-polished SCD may be bonded to semiconductors such as silicon by surface activated bonding (SAB), e.g., at room temperature and low pressure. Alternatively, fusion bonding or plasma assisted bonding (PAB) techniques involving additional thin films may be used. Fusion bonding or PAB may involve bonding at room temperature with minimal force, followed by an anneal step to improve bond strength. PAB may be performed with an optional intermediate material, e.g. silicon oxide, silicon nitride, or silicon carbo-nitride, between the diamond and semiconductor. SAB and PAB are described in detail in U.S. Provisional Application Number 63/763,416, which is attached as an Appendix. Bonding may be performed by sequential diamond-containing dielet to IC wafer, e.g., on a die bonder, collective diamond-containing dielet to IC wafer, e.g., on a wafer bonder, or diamond-containing dielet to IC die, e.g., on a die bonder. Bonding may be performed with nanoporous metals to reduce temperature and/or force, e.g. nanoporous gold, or nanoporous silver.

As in the conventional process the die structures 301 and HBM stacks 303 may be bonded to the interposer 310 through a mass solder reflow process. Underfill 312, e.g., with an epoxy mold compound, and overmolding 313, e.g., with an epoxy mold compound or encapsulation material, may then be performed. Part or all of the mold may be removed by localized removal techniques, e.g. CNC machining, or laser ablation. The surface of the diamond-containing dielet 302 may optionally be modified to facilitate subsequent removal of the overmold or encapsulation material. By way of example, an optional adhesive tape, e.g., a mold release tape 315, may be attached to the exposed surface of the diamond dielet prior to overmolding or encapsulation. Alternatively, thermal release tapes may be used. By way of another example, a thermoplastic adhesive may be applied on the diamond surface prior to overmolding 313 or encapsulation. By way of another example, the diamond surface may be coated with a fluoropolymer, polyolefin, or silicone polymer to weaken adhesion of the mold to the diamond surface and facilitate subsequent mold removal. The diamond surface may be functionalized, e.g., by surface treatments, to weaken the adhesion of the mold to the diamond surface to facilitate subsequent mold removal. The diamond may be coated by an absorption layer to facilitate laser debond of the mold. The diamond may be coated with a UV-debondable film or tape. The diamond may be coated with a pulsed-lamp-debondable film or tape Planarization, carrier wafer 314 bonding, interposer 310 thinning, and solder bumping, carrier removal, transfer to dicing tape 316, and interposer dicing may proceed as described above. The overmold or encapsulation material may be removed from the surface of the diamond dielet, e.g., facilitated by the mold release tape, at some point after solder bumping. The removal of the overmold or encapsulation material may involve one or more steps. In one implementation, the mold is removed by laser ablation, followed by a dry etch step to clean the remaining mold from the diamond surface. In another implementation, the mold is removed by laser ablation, followed by removing a mold release tape. In yet another implementation, the mold is partially removed by laser ablation followed by a laser debond step. In yet another implementation the mold is partially or completely removed by laser ablation, followed by removing a thermoplastic (adhesive) from the diamond surface, e.g., by chemical dissolution. In yet another example, the mold is partially or completely removed by laser ablation, followed by removal of a UV-debondable tape. The overmolding or encapsulation may be removed after applying vertical interconnects to a structure, such as an interposer, used to horizontally interconnect two or more chips. Various cleaning steps may be used during the exposure of the surface of the diamond-containing dielet 302. After removal from the dicing tape, each sub-assembly may be flipped and bonded to a package substrate 318, e.g., an ABF substrate, as described above.

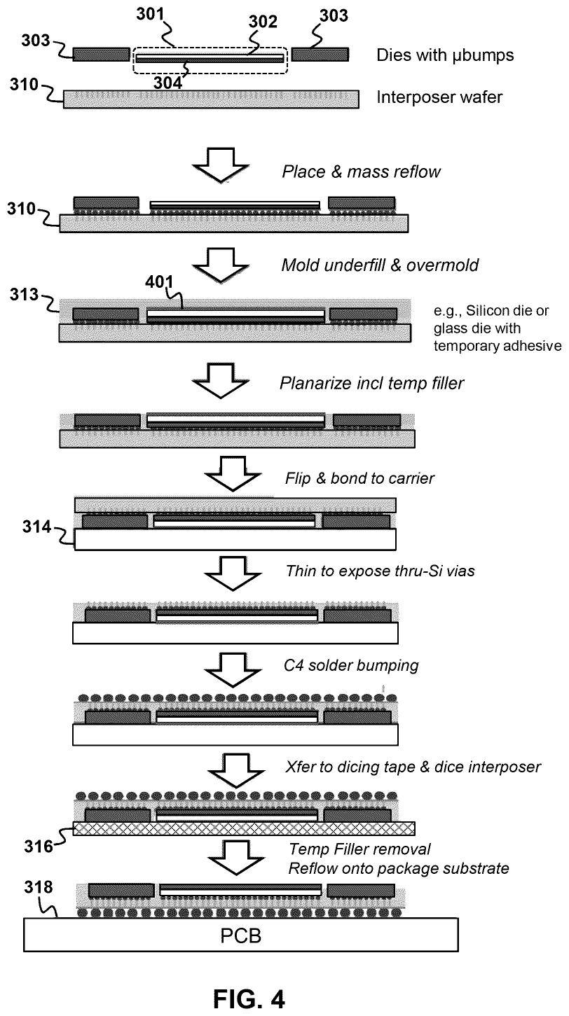

FIG. 4 illustrates a possible implementation of a modified CoWoS process flow according to aspects of the present disclosure. As in the processes described above, logic die structures 301 and HBM dies 303 with (solder) bumps are placed on an interposer wafer. As in the process of FIG. 3, the die structures include diamond dielets 302 bonded to semiconductor logic dies 304 and the die structures 301 are of lower height than the HBM stacks 303. The logic die structures and HBM stacks may be bonded to the interposer 310 through a mass solder reflow process. A temporary filler plate 401 is then attached to the exposed surface of the diamond-containing dielet 302. The filler plate 401 is thick enough to accommodate for the difference in height between the exposed surface of the diamond-containing dielet 302 and the top of the HBM stacks 303. By way of example, the filler plate 401 may be a silicon die attached to the diamond containing dielet 302 using an adhesive. Alternatively, the filler plate 401 may be made from (low-CTE) glass. In yet another example, the filler plate may be silicon carbide. In either case, the filler plate 401 has the same shape and lateral dimensions (e.g., length and width) as the diamond-containing dielet 302. The filler plate allows processing to proceed through mold underfill and overmold as in the conventional process and then covered with a molding compound underfill 312 and overmold 313, planarization, carrier wafer 314 bonding, interposer 310 thinning, and solder bumping steps described above. The temporary filler plate 401 may then be removed at some point subsequent to removal from the carrier wafer 314 and, e.g., prior to transfer to dicing tape 316 for dicing into separate die package sub-assemblies and after applying vertical interconnects to a structure used to horizontally interconnect two or more chips. Each sub-assembly may then be removed from the dicing tape, flipped again and bonded to a package substrate 318, e.g., an ABF substrate as described above. The debonding of the filler plate may be an optical debond, e.g. a laser debond with glass, or an IR laser debond with silicon. The debonding of the filler plate may be a UV-debonding step. The debonding of the filler plate may be a pulsed-lamp debonding step. The debonding step may be a step commonly used in debonding temporary carriers, e.g. optical debonding, chemical or solvent debonding, etc. The temporary filler plate may originate from an upstream processing step. The temporary filler plate may be diced from a carrier used during bonding the thinned IC wafer or die to the diamond-containing dielet(s) 302.

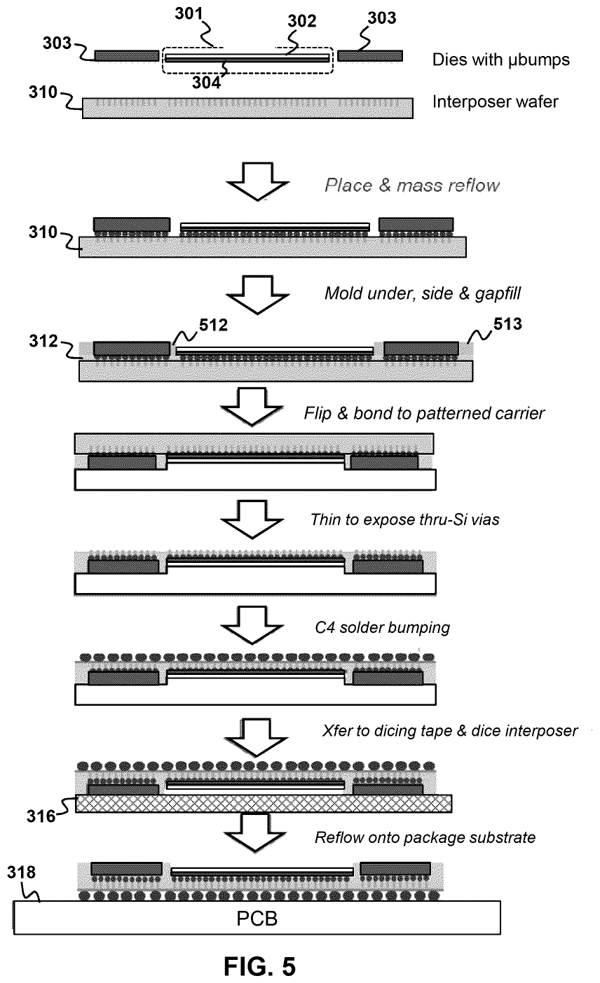

FIG. 5 illustrates yet another possible implementation of a modified CoWoS process flow according to aspects of the present disclosure. This implementation does not rely on mold removal or a filler plate. Instead, a carrier 501 configured to accommodate for the different heights of the logic die structures 301 and HBM stacks 303 may be used, e.g., a patterned carrier or a carrier as used in die bonders. By way of example, and not by way of limitation, the patterned carrier 501 may be either a carrier that has been patterned by material removal, e.g. etching, or a carrier that has been patterned by additive manufacturing, e.g. by bonding dies to a carrier. Similar to the processes in FIG. 3 and FIG. 4, logic die structures 301 and HBM dies 303 with (solder) bumps are placed on an interposer wafer 310. As in the previous two implementations, the logic die structures 301 include a thinned semiconductor logic die 304 with a diamond-containing (e.g., SCD) dielet 302 bonded to it. Once again, the height of the logic die structures 301 is less than that of the HBM 303. The dies may be bonded to the interposer 310 through a mass solder reflow process. To accommodate the patterned carrier 501, processing proceeds with mold underfill 312 and gap fill 512 or side fill 513, but not overmold. Planarization to remove excess of mold may also be omitted. Planarization to reduce height variations in HBM stacks 303 may be performed. The resulting structure is flipped and bonded to the patterned carrier 501 with raised portions of the patterned carrier accommodating the lower height of the logic die structures 301. The temporary adhesive to bond the patterned carrier may be applied by spraying or dispensing. The resulting flipped and carrier-bonded structure may then undergo interposer thinning, and solder bumping steps, followed by transfer to dicing tape 316 and dicing into separate die package sub-assemblies as described above. Each sub-assembly may then be removed from the dicing tape, flipped again and bonded to a package substrate 318 as described above.

As may be appreciated by comparing FIG. 2 with FIG. 3, FIG. 4 and FIG. 5, CoWoS process flow may be modified in a simple and straightforward fashion while obtaining a non-lidded device package, e.g., one with no copper lid and no cold plate between the diamond-containing substrate and the cooling jet.

There are a number of possible heatsink configurations discussed. For example, one or more heatsinks configured for jet impingement cooling may connect a surface with an area the same or larger than the footprint inside the device package of one or more logic elements 602 and the one or more other integrated circuit devices 603 with a fluid heat transfer medium. The fluid heat transfer medium may include, e.g., a hydrocarbon or fluorochemical or water. In some implementations, two or more heatsinks may use different fluid heat transfer media from one another. The heatsink(s) include one or more impellers configured to move the fluid heat transfer medium. The heatsink(s) may include a fluid heat transfer medium suitable for immersion cooling, and/or a fluid heat transfer medium suitable for either immersion cooling or alternative fluid heat transfer medium cooling methods, such as jet cooling or microchannel cooling. In implementations where the heatsink(s) is (are) configured for immersion cooling the diamond-containing dielets may have a surface area enhancing coating or component.

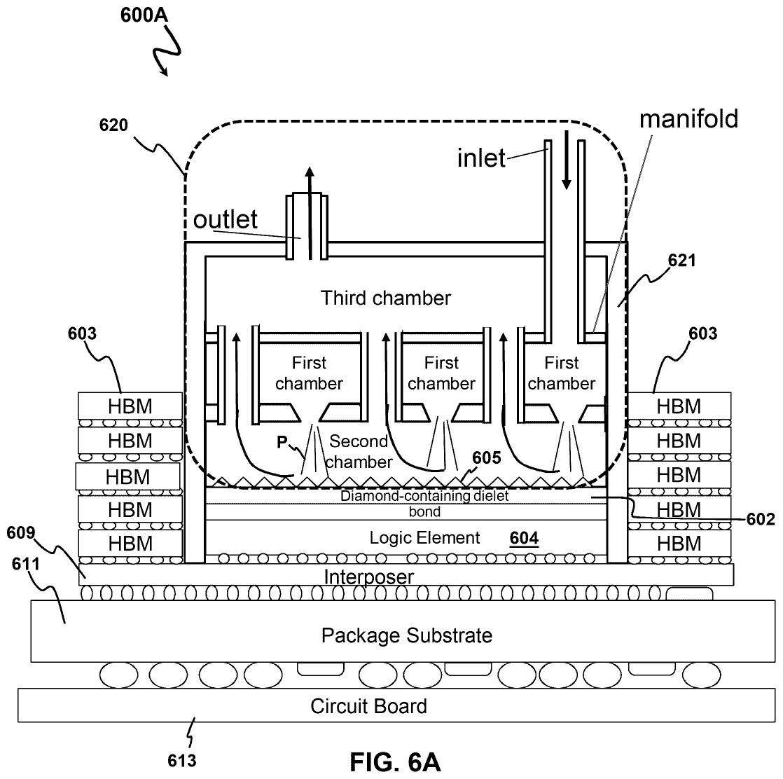

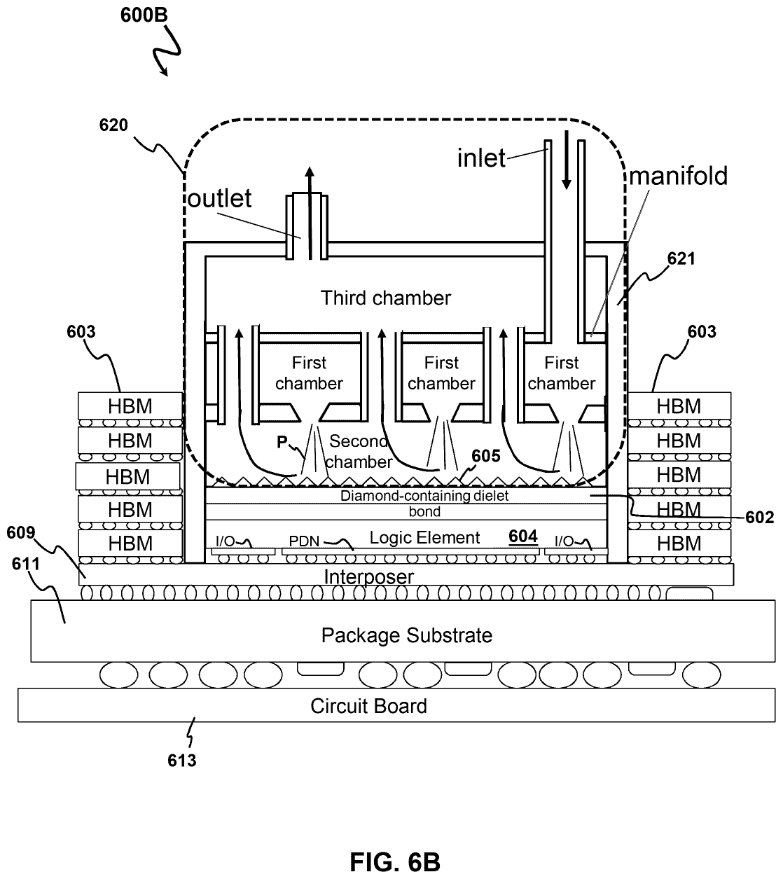

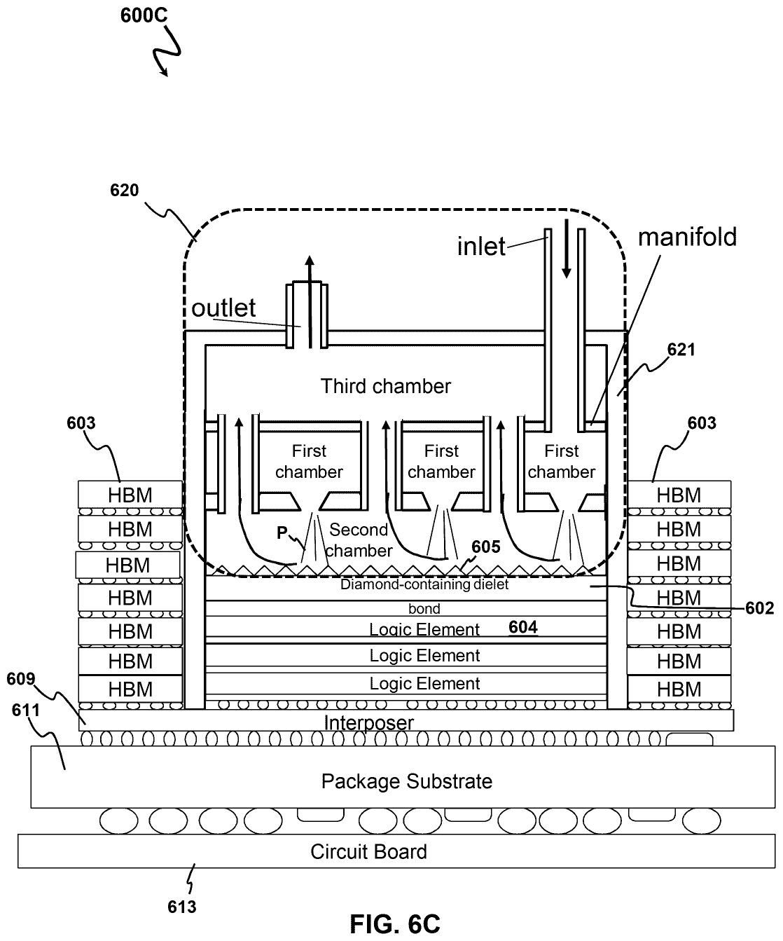

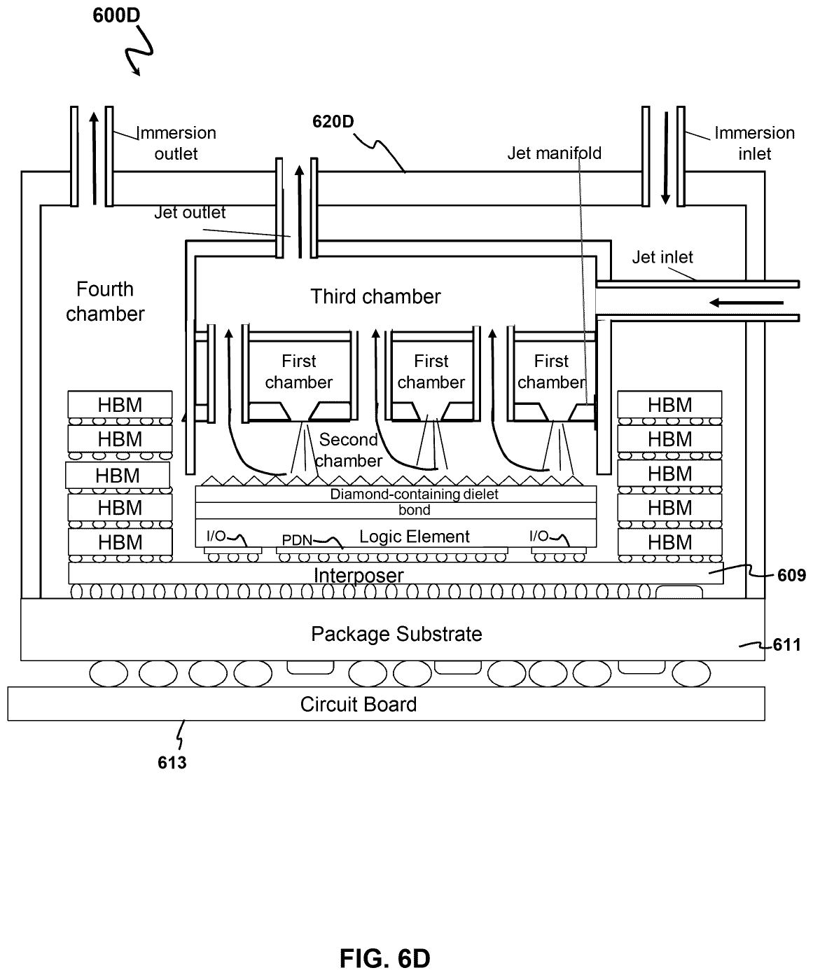

By way of example, and not by way of limitation, FIG. 6A shows a low thermal resistance device package and heatsink assembly 600A that incorporates a jet impingement cooler 620, according to an aspect of the present disclosure. Although a single logic element is shown, the device package may include two or more logic elements. The device package may include interconnects between a first logic element and a second logic element horizontally with a suitable interconnect technology, e.g., interposer, interconnect bridge, redistribution layers, and substrate. In this implementation the device package includes a logic element and stacks of other IC devices mounted to an interposer. The height of the other IC devices is greater than that of the logic element. In this example, the interposer 609 is mounted to a package substrate 611 that is, in turn, mounted to a circuit board 613. However, some implementations may omit the package substrate and the interposer may be mounted to the circuit board. At least a large part of the device package and heatsink assembly 600A may have a coefficient of thermal expansion (CTE) closely matching that of the interposer 609 (or package substrate 611), e.g., a CTE difference of 10% or less. By way of example, the interposer 609 or package substrate 611 may be made of glass with a CTE closely matching that of silicon. In such a case, at least a portion of the heatsink may be made of glass-containing materials, silicon-containing materials, polyimide-containing materials, epoxy-containing materials, molybdenum-containing materials, tungsten-containing materials, or iron-nickel-containing materials.

The bottom of the jet impingement cooler 620 may be open with the heat transfer fluid in direct contact with a diamond-containing dielet 602 bonded to an upper surface of the logic element 604. The perimeter of the cooler may be attached and sealed to the interposer to ensure fluid remains inside the cooler. Additionally, the gaps between dies may be sealed to ensure fluid remains inside the cooler. Furthermore, the cooler may have walls aligned with the gaps between the dies so that the logic element is located inside the cooler while the other IC devices are outside the cooler. While stacked high-bandwidth memory units are shown here as the other IC devices 603, it should be understood that in some implementations there may be a single IC device instead of a stack of two or more IC devices. The jet impingement cooler 620 may be attached, e.g., to the interposer, PCB, or package via standoffs or stiffeners 621. The one or more stiffeners may be configured to stabilize the heatsink 600A over the logic element 602. The stiffeners may be for example and without limitation, metal posts or tabs soldered to the circuit board or a metal processor backing bracket. The stiffeners 621 may be connected to a structure underneath the diamond-containing dielets 602, e.g., the interposer 609, package substrate 611 or circuit board 613. The stiffener 621 may be shaped as a window frame, e.g., located on the perimeter of the logic element. In some implementations the interposer 602 may include large vias through which the stiffeners 621 or stiffener fasteners pass to connect the stiffener to a backing bracket. In some implementations the backing bracket may be a metal or plastic clip which extends behind the processor assembly. Additionally the backing bracket may be a circuit board backing which extends behind an additional portion of the circuit board not covered by the processor assembly. In some implementations the stiffeners may be connected to standoff fasteners which may provide a gap between the backing and the interposer or package substrate or circuit board. The stiffeners may also be configured to stabilize the heatsink 620A over the diamond-containing dielet 602. In some implementations, the heatsink may be coupled to or integrated into the material of a package lid that is optionally connected to one or more stiffeners configured to stabilize one or more heatsinks over one or more diamond-containing dielets.

Additionally in some implementations the stiffeners may be connected to a processor assembly device package (not shown). As noted above, the device package and heatsink assembly 600A includes integrated jet impingement cooling. Jet impingement cooling may use a pressurized fluid heat transfer medium and shaped fluid path to spray a jet plume P of the heat transfer medium onto a thermally conductive surface dispersing the heat into the jet plume and away from the thermally conductive surface.

As shown in FIG. 6A, the spray plume from the jet cooler 620 is directed at a diamond-containing dielet 602 (or other thermally conductive surface) bonded to an upper surface of the logic element 604. The diamond dielet acts as a heat spreader that laterally spreads out the heat from hot spots in the logic element and also conducts the heat vertically away from the logic element. The diamond-containing dielet may be made of SCD or PCD. The surface of the diamond-containing dielet in contact with the fluid heat transfer medium may include diamond, silicon, copper, zinc, and an anti-fouling coating. As shown the surface of the diamond-containing dielet exposed to the spray from the jet cooler 620 may include one or more patterned structures 605 to increase the surface area exposed to the fluid heat transfer medium and direct the jet flow. The patterned structures may include for example and without limitation concentric rings of grooves, broken concentric rings of grooves, spiral grooves, radial channels, parallel vertical line grooves, parallel horizontal line grooves, a crosshatch pattern of grooves, microchannels, pin fin arrays, dimples and protrusions, ribbed or wavy patterns, chevron or herringbone patterns, V-shaped grooves, textures, porous coatings, etc. in the surface of the diamond dielet. Furthermore, the patterned structures may include fins or pins that are mechanically and thermally coupled to the surface of the diamond-containing dielet (or other thermally conductive surface).

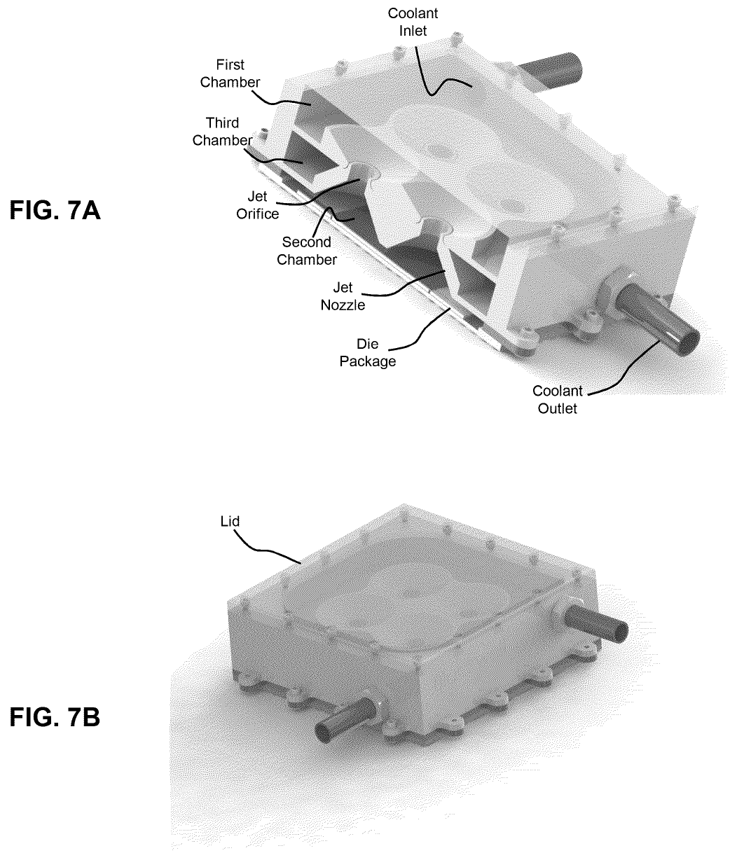

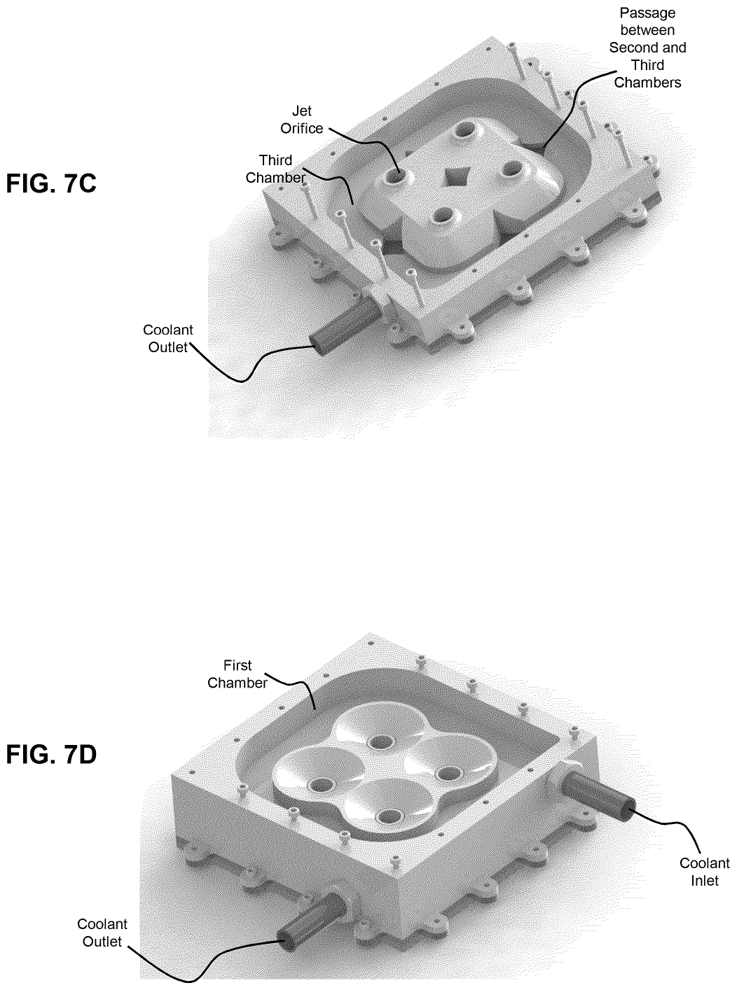

The fluid heat transfer medium may enter a first chamber through an inlet, as indicated by the downward-pointing arrow at the right of the first chamber. The fluid heat transfer medium may be accelerated from a first chamber through holes in a manifold into a second chamber and onto the exposed surface of the diamond dielet in the second chamber. The holes may further be shaped to accelerate and form the flow of heat transfer medium into a jet. The holes may be for example and without limitation venturi shaped. Additionally, in some implementations each jet may be aligned with a hot spot in the logic elements. The jet plume P of heat transfer medium may circulate through the second chamber and exit an outlet, as indicated by the upward-pointing arrow at the left of the third chamber. The height of each chamber, the locations of the inlet and outlet, the pitch of openings within each manifold, the location of the openings, the thickness of the manifold, the size and shape of each opening, the number of openings, the pattern on the thermally conductive surface, and the choice of heat transfer fluid may be optimized to ensure optimal heat transfer by optimized flow distribution, pressure distribution, flow rate control, minimal flow resistance, minimal fluid stagnation, and optionally optimized phase change control, while ensuring reliable operation, e.g., no clogging, leaking, nozzle erosion, fouling, etc. The cooler design, material and fluid choice may be optimized to reduce both pump power and thermal resistance. The fluid heat transfer medium may be for example and without limitation, water, mineral oil, an alcohol, ethylene glycol, or any combination thereof. Additionally, the cooling may be single-phase cooling or two-phase cooling. The heat transfer fluid may be a similar fluid as used for single-phase or two-phase immersion cooling. The heat transfer fluid may be a hydrocarbon, or may be a fluorochemical. The heat transfer fluid may be a dielectric coolant. The cooler may be manufactured by additive manufacturing. The cooler may be made out of polymer, polymers with fillers to reduce CTE, copper, aluminum, or silicon. The cooler may be made out of ceramics. The cooler may be manufactured out of one part. The cooler may be assembled from multiple parts, e.g., as shown in FIGS. 7A-7D and described below.

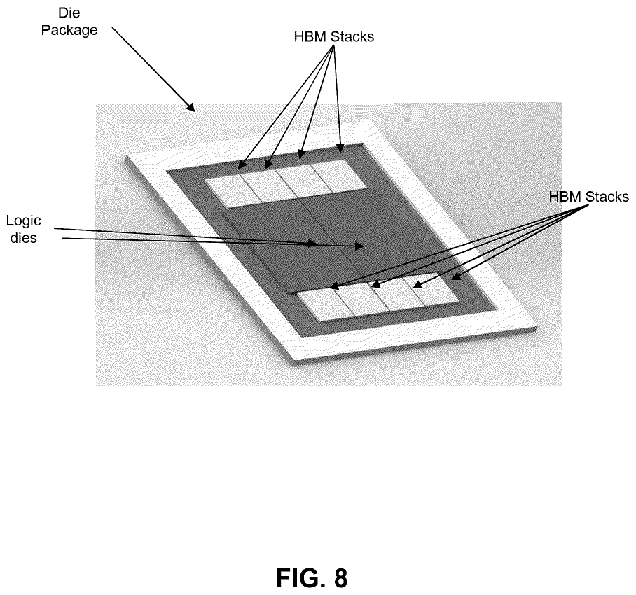

There are many possible variations on the device package and heatsink configuration shown in FIG. 6A. For example, as shown in FIG. 6B, the logic element 604 in a device package and heatsink assembly 600B may include contacts for connection to a power delivery network PDN and to an input/output signal network I/O. FIG. 8 depicts a possible layout of the HBM stacks and logic dies. The jet cooler nozzles may be configured to concentrate the cooling spray on locations that correspond to the logic dies. Furthermore, in some implementations, two or more logic elements 604 may be stacked on top of each other with the jet cooler applying spray cooling to an a diamond dielet 602 bonded to an uppermost logic element in the stack, as shown in the device package and heatsink assembly 600C depicted in FIG. 6C. In addition, in some implementations, the heatsink may be configured to implement a combination of jet cooling and immersion. For example, as shown in FIG. 6D, a device package and heatsink assembly 600D may include a jet cooler 620D having a fourth chamber that encloses both the logic element 602 and the other IC devices 603. Jet coolant is delivered from a jet inlet to the first chamber and is sprayed onto the logic element in the second chamber through openings in the jet manifold. Some of the jet coolant may recirculate through the third chamber to a jet outlet, as discussed above. Passages between the second and fourth chambers allow coolant from the jet coolers to circulate around the IC devices and exit the heat sink through an immersion outlet. Such a configuration allows for jet cooling of the logic element and immersion cooling of the other IC devices.

There are a number of different possible designs for a jet cooler. FIGS. 7A-7D illustrate a possible design. The partial cutaway view shown in FIG. 7A illustrates the arrangement of the first, second and third chambers. As seen in FIG. 7A, this example includes four jet nozzles with a venturi configuration. In this example, the jet cooler is made in three main pieces. The top piece is a lid that seals the first, as shown in FIG. 7B. The bottom piece includes the third chamber and jet orifices and coolant outlet, as shown in FIG. 7C. The jet orifices lead from the first chamber to the second chamber. The middle piece, shown in FIG. 7D, includes the first chamber and coolant inlet.

In alternative implementations one or more heatsinks configured for jet impingement cooling may include a jet cooling system having a separate cooling compartment for one or more logic elements. In a case where there are multiple cooling compartments, each cooling compartment may include one or more jet openings, one or more coolant outlets and sidewalls that isolate the compartment from neighboring compartments. Alternatively, the heatsink may include one cooling compartment for two or more logic elements with all sprayed surfaces in one plane or with at least one sprayed surface in a different plane than the others, e.g., with one sprayed surface at a different height than the others. In other implementations there may be one or more heatsinks configured for jet impingement cooling that include a jet cooling system having a separate cooling compartment for one or more device packages.

Aspects of the present disclosure enable integration of diamond-containing substrates, e.g., SCD, with high-power chips while managing CTE mismatch and resulting warpage from combining thick or large copper plates or lids with SCD. Integration of diamond-containing substrates with high-power chips according to aspects of the present disclosure allows for direct jet impingement cooled SCD bonded to thinned-silicon chips in a non-lidded package. Such integration is compatible with existing and proposed 2.5D chip packages with minimal changes to existing CoWoS(-L) process flow. Use of diamond-containing dielets bonded to IC wafers or dies whose passive semiconductor material has been thinned advantageously avoids use of a (reconstituted) 300 mm diamond-containing wafer. The solutions described hereinabove may be geared towards high-power data centers that are liquid cooled and may be readily adapted to work with future chip designs that seek to fully exploit the new thermal advantages of SCD.

Temporary bonding may be used in multiple steps during the processing. Temporary bonding may be used for thinning the IC wafer or bonding the filler plate. The temporary carrier or filler plate may be made of glass, silicon, sapphire, quartz, or silicon carbide. The temporary carrier may match in CTE with the bonded wafer or dies. The temporary carrier or filler plate may have through holes, e.g., to aid in chemical or solvent debonding. The temporary carrier or filler plate may be optically transparent, e.g., to aid in optical debonding. The temporary carrier may support electrostatic bonding and debonding. The temporary carrier may contain a buried layer or surface layer that supports optical debonding. The temporary adhesive may be organic or inorganic. The temporary adhesive may cross-link or be a thermoplastic. Alternatively the temporary bonding may be performed by Van Der Waals bonding, e.g. based on hydrophilic surfaces. The temporary adhesive may contain one coating, or more than one coating. One of these coatings may absorb light, e.g., laser, UV, or pulsed light, which aids in debonding. The temporary carrier or filler plate may have alignment marks. The temporary carrier may be bonded by a permanent bonding method, e.g., SAB, ADB, PAB, or TCB. Examples of these bonding methods are described, e.g., in U.S. patent application Ser. No. 18/761,091, which is incorporated herein by reference, e.g., at paragraphs 0056-0089 and corresponding FIGS. 8A-8F. The temporary bonding may be accomplished by a mobile electrostatic carrier. The final removal of the temporary carrier or filler plate may be based on (visible or IR) laser debonding, UV debonding, thermal (slide) debonding, chemical debonding, (thermo-)mechanical debonding, (thermal) solvent debonding, electrostatic debonding, or abrasive and/or chemical removal of the temporary carrier.

Jet impingement cooling is one type of heatsink that may be assembled to the chip package (die package, or device package). A heatsink is a thermal management component used to dissipate heat from the high-power chips into the surrounding environment, preventing overheating of the high-power chips. Other heatsinks in addition to jet impingement coolers may be microchannel coolers, cold plates, spray coolers, immersion coolers, or a combination of two or more of these heatsinks. The heatsink may be directly attached to the silicon of the chip package. The heatsink may be directly attached to the interposer of the chip package. The heatsink may be directly attached to the package substrate of the chip package. The heatsink may be directly attached to the PCB board underneath the chip package. In alternative applications, the heatsink may be attached to two or more locations, e.g. the package substrate and the PCB board underneath the chip package. The heatsink may be attached to the server or server rack. A heatsink may conduct the heat away from the chip and dissipate the heat into the air or a liquid coolant. The heatsink may be manufactured by additive manufacturing or subtractive manufacturing. The heatsink may be manufactured from a material that closely matches the material to which the heatsink is attached. For example, the heatsink may be manufactured from low-CTE material when bonded to silicon, or glass. The heatsink may be manufactured from metal, e.g. copper, when attached to the PCB board. The heatsink may be attached by using a temporary bond, e.g. clamping a sealing ring. The heatsink may be attached by using a permanent bond, e.g. an epoxy bond. The heatsink may be attached by glass frit, e.g., when bonding glass to glass, or glass to metal. Hermetic seals may be formed by TLPB. The cooling fluid may be a one-phase cooling fluid, or a two-phase cooling fluid. The diamond-containing dielet may be coated with a boiling-enhancement coating, e.g. for two-phase cooling.

Packaging substrates used for advanced chip packaging may include ABF (Ajinomoto Build-up Film) substrates, BT (bismaleimide-triazine) resin substrates, (low-CTE) glass substrates, or ceramic (e.g. aluminum nitride, aluminum oxide) substrates. Interposers used for advanced chip packaging may include silicon, silicon carbide, diamond, organic build-up substrates, or glass. The device package may include interconnects between two or more dies horizontally with one or more of the interconnect technologies selected from a list consisting of: interposer, interconnect bridge, redistribution layers, and substrate. The packaging may be performed on a wafer level or a panel level. The package may be a 2.5D package, e.g. with one or more logic dies, and one or more HBM stacks on an interposer on a substrate. The advanced chip package may include photonics, e.g. silicon photonics, for high-speed, energy-efficient, data transmission. The advanced chip package may include co-packaged optics (CPO). The advanced chip package may include photonic integrated circuits (PIC). The advanced chip package may integrate photonic integrated circuits (PICs) with electronic integrated circuits (EICs).

While the above mainly discusses a CoWoS system or CoWoS process flow, or more generally, a chip-on-interposer-on-substrate system, it should be understood that aspects of the present disclosure are not so limited and may be implemented in any type of integrated circuit device packaging system including but not limited to 2D, 2.1D, 2.5D, other 3D, and 3.5D packaging systems. As used herein, “2D packaging” refers to a traditional method of packaging semiconductor devices where one or multiple integrated circuits (ICs) or chips are mounted side-by-side on a single (organic laminate) packaging substrate, such as a printed circuit board (PCB), without stacking them vertically. The components are arranged in a single plane, forming a two-dimensional layout. “2.5D packaging” refers to a packaging technique in which multiple integrated circuit chips (sometimes called “dies”) are placed side-by-side on a common interposer, e.g., silicon or an organic interposer, which provides high-density interconnections between the chips. The interposer sits on a packaging substrate. “2.5D packaging” may also refer to the use of interconnect bridges, e.g. embedded bridges. “2.1D packaging” refers to a packaging technique where a redistribution layer (RDL) is used instead of a silicon interposer. “3D packaging” refers to a packaging technology where multiple semiconductor dies (chips) are stacked vertically on top of each other within a single package and interconnects are made vertically between stacked dies, e.g., using through-silicon vias (TSVs) therefore offering a higher packaging density than 2D, 2.1D or 2.5D packaging. “3.5D packaging” refers to a packaging technique that uses a combination of vertically stacked dies and interposers. Besides TSMC's CoWoS (chip-on-wafer-on-substrate), other similar advanced chip packages may benefit from one or more implementations, e.g., Intel's EMIB and Foveros, Samsung's I-Cube or X-Cube, ASE's FoCoS, and Amkor's S-Connect. These advanced chip packages may contain dies with standard power delivery, where both the I/O signal network and power network are located on the same side of the IC devices, e.g. CMOS transistors. These advanced chip packages may contain dies with backside power delivery, where the power delivery network and the I/O signal network both are located on the opposite side of the CMOS transistors, e.g. with the CMOS transistors sandwiched between both networks. These advanced chip packages may contain silicon photonics. These advanced chip packages may contain dies with two or more layers of transistors stacked on top of each other within the same die, e.g. one layer mainly designed for computation, where the other layer is mainly designed for a memory function, e.g. random-access memory. The IC devices may be FinFETs, the IC devices may be gate-all-around FETs.

While the above is a complete description of the preferred embodiment of the present invention, it is possible to use various alternatives, modifications and equivalents. Therefore, the scope of the present invention should be determined not with reference to the above description but should, instead, be determined with reference to the appended claims, along with their full scope of equivalents. Any feature described herein, whether preferred or not, may be combined with any other feature described herein, whether preferred or not. In the claims that follow, the indefinite article “A”, or “An” refers to a quantity of one or more of the items following the article, except where expressly stated otherwise. The appended claims are not to be interpreted as including means-plus-function limitations, unless such a limitation is explicitly recited in a given claim using the phrase “means for.”

What is claimed is:

1. A low thermal resistance device package and heatsink assembly, comprising:
a device package containing one or more logic elements and one or more other integrated circuit devices mounted to a package substrate, wherein the one or more other integrated circuit devices are characterized by a greater height above a surface of the package substrate than the one or more logic elements; and
one or more heatsinks, wherein each heatsink contains one or more chambers configured for a fluid heat transfer medium, and wherein a surface of the one or more logic elements is thermally coupled to the fluid heat transfer medium.

2. The assembly of claim 1 wherein a diamond-containing die is bonded to the one or more logic elements with the one or more logic elements sandwiched between the package substrate and the diamond-containing dielet.

3. The assembly of claim 2 wherein the diamond-containing dielet is bonded by sintering, transient liquid phase bonding, or laser assisted bonding.

4. The assembly of claim 2 wherein the diamond-containing dielet is bonded by either: thermocompression bonding (TCB), soldering, eutectic bonding, surface activated bonding (SAB), atomic diffusion bonding (ADB), plasma assisted bonding (PAB), ultrasonic bonding (UB), brazing, or adhesive bonding.

5. The assembly of claim 2 wherein the roughness on at least one side of the diamond-containing dielet is larger than 2 nanometers.

6. The assembly of claim 2 wherein at least one diamond-containing dielet is a single crystal diamond dielet.

7. The assembly of claim 2 wherein the diamond-containing dielets are all single crystal diamond dielets.

8. The assembly of claim 2 wherein at least one diamond-containing dielet is a polycrystalline diamond dielet.

9. The assembly of claim 2, wherein at least one diamond-containing dielet is a composite diamond die composed of diamond and a metal, wherein the metal includes one or more of the following: copper, silver, gold, aluminum, and zinc.

10. The assembly of claim 2 wherein the diamond-containing dielets each have a thickness of between 100 micrometers and 800 micrometers.

11. The assembly of claim 2 wherein at least one of the diamond-containing dielets has a thermal conductivity higher than 2000 W/m-K.

12. The assembly of claim 2 wherein a main surface of at least one of the one or more diamond-containing dielets includes a crystal orientation of (100), (110), (111), or (113).

13. The assembly of claim 2 wherein at least one diamond-containing dielet is a single crystal diamond with a size larger than 20 millimeters in one direction.

14. The assembly of claim 1 wherein the one or more logic elements are part of one or more semiconductor dies with a semiconductor thickness below 100 micrometers.

15. The assembly of claim 1 wherein the device package includes interconnects between a first logic element and a second logic element horizontally with one or more of the interconnect technologies selected from a list consisting of: interposer, interconnect bridge, redistribution layers, and substrate.

16. The assembly of claim 1 wherein the one or more logic elements are connected to a power delivery network and an input and output signal network.

17. The assembly of claim 16 wherein the power delivery network and an input and output signal network are located on the same side of the one or more logic elements.

18. The assembly of claim 1 wherein two or more logic elements are stacked on top of each other.

19. The assembly of claim 1, wherein the one or more other integrated circuit devices include one or more high-bandwith memory (HBM) stacks.

20. The assembly of claim 1, wherein the one or more heatsinks are configured for jet impingement cooling.

21. The assembly of claim 20, wherein the one or more heatsinks are configured for jet impingement cooling and the one or more heatsinks configured for jet impingement cooling connects a surface with an area the same or larger than the footprint inside the device package of the one or more logic elements and the one or more other integrated circuit devices with a fluid heat transfer medium.

22. The assembly of claim 21, wherein at least a large part of the one or more heatsinks has a coefficient of thermal expansion closely matching that of the package substrate.

23. The assembly of claim 21, wherein the package substrate is glass with a coefficient of thermal expansion closely matching silicon, and at least a portion of the one or more heatsinks is made of glass-containing materials, silicon-containing materials, polyimide-containing materials, epoxy-containing materials, molybdenum-containing materials, tungsten-containing materials, or iron-nickel-containing materials.

24. The assembly of claim 20, wherein the one or more heatsinks are configured for jet impingement cooling and include a jet cooling system having a separate cooling compartment for the footprint inside the device package of the one or more logic elements and the one or more other integrated devices.

25. The assembly of claim 20, wherein the one or more heatsinks are configured for jet impingement cooling and include a jet cooling system having a separate cooling compartment for one or more logic elements.

26. The assembly of claim 25, wherein each cooling compartment includes one or more jet openings, one or more coolant outlets and sidewalls that isolate the compartment from neighboring compartments.

27. The assembly of claim 25, wherein the one or more heatsinks configured for jet cooling include one cooling compartment for two or more logic elements with all sprayed surfaces in one plane.

28. The assembly of claim 25, wherein the one or more heatsinks configured for jet cooling include one cooling compartment for two or more logic elements with at least one sprayed surface in a different plane than the other(s).

29. The assembly of claim 20, wherein the one or more heatsinks are configured for jet impingement cooling and include a jet cooling system having a separate cooling compartment for one or more device packages.

30. The assembly of claim 1 wherein at least one heatsink includes one or more nozzles configured to spray the fluid heat transfer medium against a thermally conductive surface thermally connected to one or more logic elements.

31. The assembly of claim 30 wherein the thermally conductive surface includes one or more patterned structures configured to improve conduction of heat to the fluid heat transfer medium.

32. The assembly of claim 31 wherein the one or more patterned structures include fins or pins mechanically and thermally coupled to the thermally conductive surface.

33. The assembly of claim 1 wherein at least one fluid heat transfer medium is a hydrocarbon or fluorochemical.

34. The assembly of claim 1 wherein at least one fluid heat transfer medium contains water.

35. The assembly of claim 1 wherein at least two heatsinks use different fluid heat transfer media from one another.

36. The assembly of claim 1 wherein the one or more heatsinks further include one or more impellers configured to move the fluid heat transfer medium.

37. The assembly of claim 1 wherein one or more heatsinks include a fluid heat transfer medium suitable for immersion cooling, and one or more heatsinks include a fluid heat transfer medium suitable for either immersion cooling or alternative fluid heat transfer medium cooling methods.

38. The assembly of claim 1, wherein the one or more heatsinks are configured for microchannel cooling.

39. The assembly of claim 1, wherein the one or more heatsinks are configured for immersion cooling.

40. The assembly of claim 39 wherein the one or more diamond-containing dielets have a surface area enhancing coating or component.

41. The assembly of claim 2, wherein the one or more heatsinks are configured for jet cooling and where each jet cooler is configured to cool one or more diamond-containing dielets.

42. The assembly of claim 2 wherein the one or more heatsinks include one or more manifolds, one or more chambers, one or more inlets, and one or more outlets configured for jet impingement cooling with the fluid heat transfer medium in direct contact with the one or more diamond-containing dielets.

43. The assembly of claim 2 wherein the surface of the one or more diamond-containing dielets in contact with the fluid heat transfer medium, contains at least one of diamond, silicon, copper, zinc, and an anti-fouling coating.

44. The assembly of claim 2 wherein the one or more heatsinks are coupled to one or more stiffeners configured to stabilize the one or more heatsinks over the one or more diamond-containing dielets.

45. The assembly of claim 44 wherein the one or more stiffeners are connected to a circuit board underneath the one or more diamond-containing dielets.

46. The assembly of claim 44 wherein the one or more stiffeners are connected to a backing bracket behind a circuit board underneath the one or more diamond-containing dielets.

47. The assembly of claim 2 wherein the one or more heatsinks are integrated into the material of a package lid wherein the lid is optionally connected to one or more stiffeners configured to stabilize the one or more heatsinks over the one or more diamond-containing dielets.

48. The assembly of claim 2 wherein the one or more heatsinks are coupled to the top of a lid and wherein the lid is optionally connected to the one or more stiffeners configured to stabilize the one or more heatsinks over the one or more diamond-containing dielets.

49. A method for fabricating a semiconductor chip package, comprising:
bonding a diamond-containing dielet to a logic die made of a semiconductor material to form a logic die structure;
mounting the logic die structure to a package substrate with the logic die sandwiched between the diamond-containing dielet and the package substrate, wherein a surface of the diamond-containing dielet is exposed; and
mounting one or more other integrated circuit devices to the package substrate, wherein the one or more other integrated circuit devices are characterized by a greater height above a surface of the package substrate than the logic die structure.

50. The method of claim 49, wherein mounting the logic die structure and the one or more other integrated circuit devices to package substrate includes horizontally interconnecting two or more chips and in which an overmold or encapsulation process is adapted to accommodate for the difference in height between the logic die structure and the one or more other integrated circuit devices.

51. The method of claim 50, wherein the overmold or encapsulation process is adapted by overmolding or encapsulating the logic die structure and the one or more other integrated circuit devices and removing the overmold or encapsulation material from the logic die structure to expose the surface of the diamond-containing dielet after applying vertical interconnects to a structure used to horizontally interconnect two or more chips.

52. The method of claim 51, wherein overmolding or encapsulating the logic die structure and the one or more other integrated circuit devices and removing the overmold or encapsulation material from the logic die structure includes modifying a surface of the diamond-containing dielet to facilitate removal of the overmold or encapsulation material therefrom.

53. The method of claim 52, wherein modifying a surface of the diamond-containing dielet to facilitate removal of the overmold or encapsulation material therefrom includes attaching an adhesive tape to the surface of the diamond dielet prior to overmolding or encapsulating the logic die structure.

54. The method of claim 52, wherein modifying a surface of the diamond-containing dielet to facilitate removal of the overmold or encapsulation material therefrom includes an optical debond step.

55. The method of claim 52, wherein modifying a surface of the diamond-containing dielet to facilitate removal of the overmold or encapsulation material therefrom includes attaching a thermoplastic material to the surface of the diamond dielet prior to overmolding or encapsulating the logic die structure.

56. The method of claim 50, wherein the overmold or encapsulation process is adapted by attaching a filler plate to the surface of the diamond-containing dielet before overmolding or encapsulating the logic die structure and one or more integrated circuit devices, wherein the filler plate is of the same lateral dimensions as the diamond dielet and thick enough to accommodate for a difference in height between the surface of the diamond-containing dielet and a top of the one or more other integrated circuit devices.

57. The method of claim 56, wherein the chip packaging process includes removing the filler plate after applying vertical interconnects to a structure used to horizontally interconnect two or more chips.

58. The method of claim 56, wherein the filler plate includes a semiconductor die.

59. The method of claim 56, wherein the filler plate includes a glass plate.

60. The method of claim 56, wherein the filler plate is removed by optical debonding.

61. The method of claim 49, wherein the chip packaging process is modified by use of a patterned carrier configured to accommodate for the different heights of the logic die assembly and the one or more other integrated circuit devices.

62. The method of claim 61, wherein the chip packaging process includes underfill and gap fill, but not overmold or encapsulation.

63. The method of claim 61, wherein the chip packaging process includes underfill and gap fill, but not overmold or encapsulation and not removal of excess overmold or encapsulation material by planarization.
